(19) United States
(12) Patent Application Publication
(10) Pub. No.: US 2013/0168242 A1
(43) Pub. Date: Jul. 4, 2013

(54) MAGNETIC CORE FOR CYLINDRICAL MAGNETRON SPUTTERING TARGET

(71) Applicants: TENG-TSUNG HUANG, Tu-Cheng (TW); HUA-YONG XU, Shenzhen City (CN); ZHEN-ZHANG LIU, Shenzhen City (CN)

(72) Inventors: TENG-TSUNG HUANG, Tu-Cheng (TW); HUA-YONG XU, Shenzhen City (CN); ZHEN-ZHANG LIU, Shenzhen City (CN)

(73) Assignees: HON HAI PRECISION INDUSTRY CO. LTD., Tu-Cheng (TW); HONG FU JIN PRECISION INDUSTRY (ShenZhen) CO., LTD., Shenzhen City (CN)

(21) Appl. No.: 13/534,336

(22) Filed: Jun. 27, 2012

(30) Foreign Application Priority Data
Dec. 30, 2011 (CN) 201110454429.4

(51) Int. Cl. C23C 14/35

(52) U.S. Cl. 204/298.21

(57) ABSTRACT

A magnetic core for cylindrical magnetron sputtering target includes a housing and a magnet array. The housing includes a mounting plate and a base. The magnet array is mounted in the mounting plate and is enclosed in the housing. The magnet array includes a plurality of magnet segments stacked end to end.

### BACKGROUND

1. Technical Field

The present disclosure relates to magnetic cores, especially to a magnetic core for a cylindrical magnetron sputtering target.

2. Description of Related Art

Vacuum sputtering devices receive sputtering targets. The targets are generally hollow cylindrical targets having magnetic cores mounted on the inner surfaces of the hollow portions of the targets. Commonly, three notches are first defined in the inner surface of the target along the axial direction. The notches are equidistantly distributed. Then a number of magnets are mounted in the notches to form a magnetic core of the cylindrical target. However, it is time consuming and costly to form the notches in the inner surfaces of the targets, as well as the mounting of the magnets to the notches. Additionally, during a deposition process, the cylindrical target must be cooled by cooling water which fills and flows through the cylindrical target. As a result, the magnets mounted in the inner surface of the target will be immersed in the cooling water during the deposition process. The magnets are prone to damage by the cooling water. Thus, the lifespan of the magnets is reduced.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an exemplary embodiment of an assembled magnetic core.

FIG. 2 is a partial exploded view of the magnetic core shown in FIG. 1.

FIG. 3 is an enlarged view of region III shown in FIG. 2.

### DETAILED DESCRIPTION

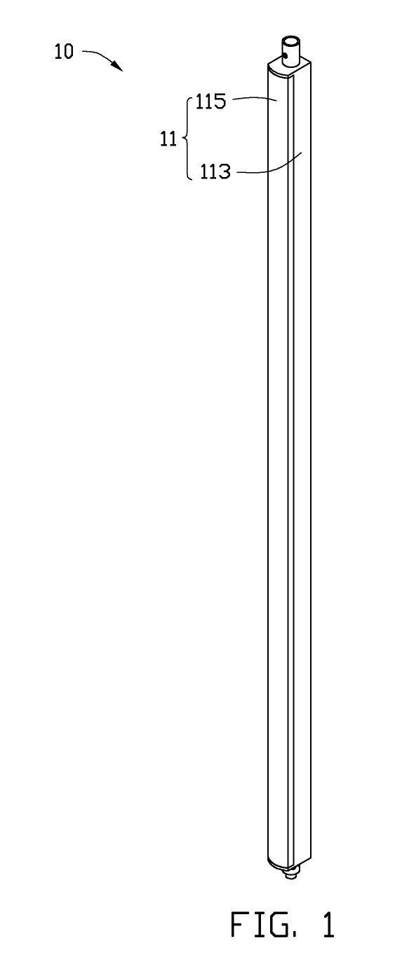

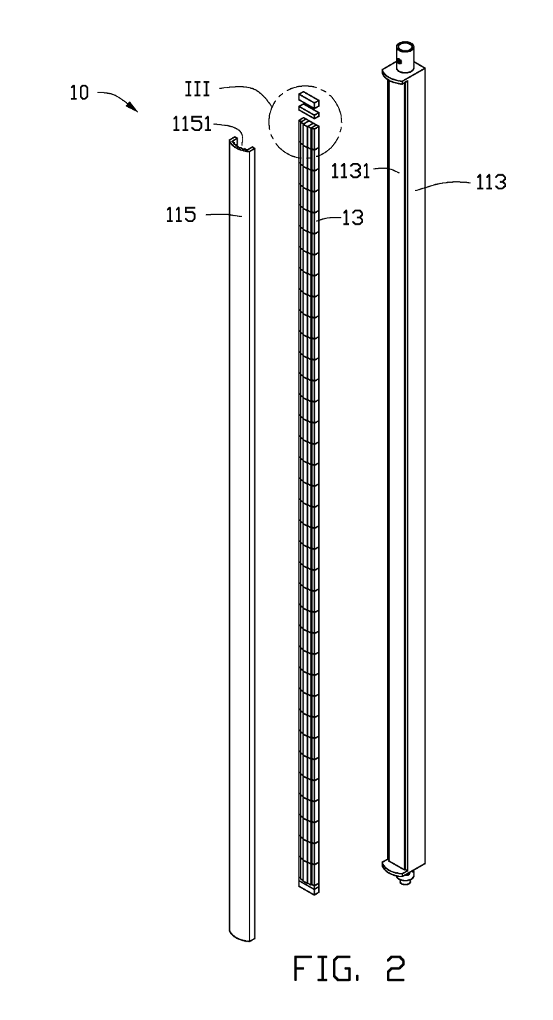

FIGS. 1 and 2, illustrate a magnetic core 10 according to one exemplary embodiment. The magnetic core 10 includes a housing 11 and a magnet array 13. The magnet array 13 is mounted and secured in the housing 11.

The housing 11 includes a base 113 and a mounting plate 115. The base 113 defines a first notch 1131. The mounting plate 115 defines a second notch 1151. The magnet array 13 is mounted and secured in the second notch 1151 of the mounting plate 115. The base 113 is welded to the mounting plate 115 with the mounting plate 15/magnet array 13 being received in first notch 1131, thus enclosing the magnet array 13 in the housing 11. Alternatively, the base 113 can be incorporated to the mounting plate 115 by adhesives. The base 113 and the mounting plate 115 are both made of stainless steel.

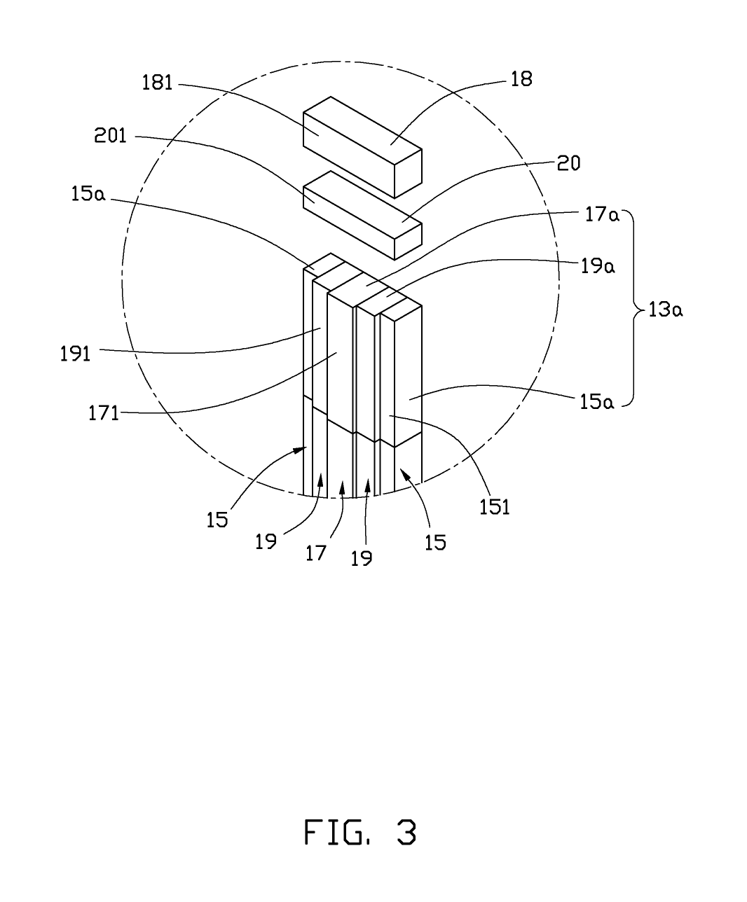

Referring to FIG. 3, the magnet array 13 includes a plurality of magnet segments 13a stacked end to end, and a third magnet 18 and a radial separating block 20 at each end of the magnet array 13, with the radial separating block 20 positioned between the outermost magnet segments 13a and the third magnet 18. Each magnet segment 13a includes two first magnets 15a, a second magnet 17a, and two longitudinal separating blocks 19a. The separating blocks 19a are respectively located on the opposite sides of the second magnet 17a. Each first magnet 15a is located on the side of each separating block 19a. Each first magnet 15a defines a mounting surface 151. The second magnet 17a defines a mounting surface 171. Each separating block 19a defines a mounting surface 191. The separating blocks 19a may be aluminum blocks, plastic blocks, or ceramic blocks. The separating blocks 19a are nonmagnetic. Each third magnet 18 defines a mounting surface 181. When the magnet array 13 is mounted in the second notch 1151, the mounting surfaces 151, 171, 191, and 181 all contact with the mounting plate 115.

Each first magnet 15a and second magnet 17a is separated by a separating block 19a, which allow the first magnets 15a and the second magnet 17a to produce a desired sputtering magnetic field. The second magnet 17a is larger than each first magnet 15a, which gives the magnetic field a more suitable distribution. The mounting surfaces 151, 171, 191, and 181 are not at a same plane, which also provides the magnetic field a better distribution.

The two third magnets 18 respectively located at the two ends of the magnet array 13, allows the magnetic field of the magnet array 13 to form an enclosed magnetic field, with which the sputtering uniformity of the target will be improved and the lifespan of the target prolonged. The separating block 20 is positioned between the outermost magnet segments 13a and the third magnet 18 to provide the enclosed magnetic field a better distribution. The separating block 20 has a mounting surface 201 which may directly contact the mounting plate 115. The separating block 20 may be aluminum blocks, plastic blocks, or ceramic blocks. The separating block 20 is nonmagnetic.

The first magnets 15a, the second magnet 17a, and the third magnets 18 are all made of samarium cobalt alloy.

During assembling of the magnetic core 10, a plurality of second magnets 17a are mounted in the mounting plate 115 and stacked with each other end to end to form a second magnet group 17. A plurality of separating blocks 19a are mounted in the mounting plate 115 and located on the opposite sides of the second magnet group 17 to form two separating block groups 19. A plurality of first magnets 15a are mounted in the mounting plate 115 and located on the sides of the separating block groups 19 to form two first magnet groups 15. Finally, a separating block 20 and a third magnet 18 are mounted orderly in the mounting plate 115 at each end of the magnet array 13. Then, to enclose the magnet array 13 in the housing 11, the base 113 is welded or is adhered to the mounting plate 115. As such, the magnetic core 10 is finished.

Before the magnet array 13 is mounted in the mounting plate 115, the mounting surfaces 151, 171, 191, 181, and 201 may be all coated with adhesive layers to enhance the mounting security of the magnet array 13 to the mounting plate 115.

The magnetic core 10 of the exemplary embodiment can be mounted in a hollow cylindrical target (not shown) along the axis of the target. Because the magnet array 13 is enclosed by the housing 11, the magnets of the magnet array 13 will not be damaged by the cooling water, thus prolongs the lifespan of the magnets.

Additionally, the magnetic core 10 of the exemplary embodiment can be easily assembled, and it is easily to mount the magnetic core 10 in a hollow cylindrical target.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A magnetic core for cylindrical magnetron sputtering target, the magnetic core comprising:
a housing comprising a mounting plate and a base; and
a magnet array mounted in the mounting plate and being enclosed in the housing, the magnet array comprising a plurality of magnet segments stacked end to end.

2. The magnetic core as claimed in claim 1, wherein each magnet segment comprises a second magnet, two longitudinal separating blocks respectively located on the opposite sides of the second magnet, and two first magnets respectively located on the side of each separating block.

3. The magnetic core as claimed in claim 3, wherein the longitudinal separating blocks are aluminum blocks, plastic blocks, or ceramic blocks.

4. The magnetic core as claimed in claim 1, wherein the base defines a first notch, the mounting plate defines a second notch, the magnet array is mounted and secured in the second notch of the mounting plate.

5. The magnetic core as claimed in claim 2, wherein the magnet array further comprises two third magnets, one third magnet located at each end of the magnet array.

6. The magnetic core as claimed in claim 5, wherein the magnet array further comprises two radial separating blocks, each radial separating block is positioned between each third magnet and the outermost magnet segments.

7. The magnetic core as claimed in claim 6, wherein the radial separating blocks are aluminum blocks, plastic blocks, or ceramic blocks.

8. The magnetic core as claimed in claim 2, wherein each second magnet is larger than each first magnet.

9. The magnetic core as claimed in claim 2, wherein the separating blocks, the first magnets, and the second magnet have mounting surfaces, the mounting surfaces are not at a same plane.

10. The magnetic core as claimed in claim 9, wherein the mounting surfaces are coated with adhesive layers.

11. The magnetic core as claimed in claim 6, wherein the third magnets and the radial separating blocks have mounting surfaces, the mounting surfaces are coated with adhesive layers.

12. The magnetic core as claimed in claim 1, wherein the base is welded to the mounting plate to enclose the magnet array in the housing.

13. The magnetic core as claimed in claim 1, wherein the base is incorporated to the mounting plate by adhesives to enclose the magnet array in the housing.

14. The magnetic core as claimed in claim 5, wherein the first magnets, the second magnet, and the third magnets are all made of samarium cobalt alloy.

15. The magnetic core as claimed in claim 1, wherein the base and the mounting plate are both made of stainless steel.
